(19) United States
(12) Patent Application Publication
(10) Pub. No.: US 2010/0123499 A1
(43) Pub. Date: May 20, 2010

(54) INFORMATION SYSTEM, SEMICONDUCTOR DEVICE AND CONTROL METHOD THEREFOR

(75) Inventors: Hiroki TAKAHASHI, Tokyo (JP); Toru Ishikawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/619,396

(22) Filed: Nov. 16, 2009

(30) Foreign Application Priority Data
Nov. 14, 2008 (JP) 2008-292583

(51) Int. Cl. H03L 7/06

(52) U.S. Cl. 327/158

(57) ABSTRACT

An information system with an enhanced effect in reducing jitter with a short period. An input clock signal CLKi is output via a voltage-controlled delay circuit 14 as an output clock signal CLKo, and an amount of delay in the voltage-controlled delay circuit 14 is controlled based on the result of comparison of a phase of the input clock signal CLKi and that of the output clock signal CLKo. A phase correction circuit 21 receives the input clock signal CLKi and the output clock signal CLKo. If, after the DLL circuit has become locked, the input clock signal and the output clock signal are out of phase relative to each other, the phase correction circuit 21 corrects the phase of the input clock signal CLKi based on a phase of the output clock signal CLKo to output a signal to the variable delay circuit 14 (FIG. 1).

### REFERENCE TO RELATED APPLICATION

This application is based upon and claims the benefit of the priority of Japanese patent application No. 2008-292583, filed on Nov. 14, 2008, the disclosure of which is incorporated herein in its entirety by reference thereto.

This invention relates to an information system having an interface that delivers and receives the address command information or the data information in synchronism with a system clock. More particularly, it relates to a semiconductor device including a DLL (Delay Locked Loop) circuit run in operation by a system clock, and a control method therefor.

### BACKGROUND

In the DLL circuit, the phase of an input clock signal CLKi (reference clock) is compared by a phase comparator circuit (PD) to that of a feedback signal of a clock signal CLKo output from a variable delay circuit, such as a voltage controlled delay line. The result of comparison is reflected in the delay time of the variable delay circuit. Control is managed so that the phase of the clock signal CLKo is caused to lead or lag in such a manner that the clock signal CLKo is ultimately in phase with the clock signal CLKi (locked state).

Once the locked state is established, the operation of the DLL circuit is usually discontinued for reducing the power consumption. Therefore, if the clock signal CLKi suffers from jitter, the clock signal CLKo is output, after the locked state is a established, as the jitter of clock signal CLKi has been reflected in the output clock signal CLKo.

Patent Document 1 discloses a DLL circuit in which, even in case the clock signal CLKi suffers from jitter, the amount of such jitter in the clock signal CLKo may be reduced. This DLL circuit is of the hierarchical configuration, and includes a DLL circuit section with a unit of delay for rough adjustment and another DLL circuit section with a unit of delay for fine adjustment which is smaller than the unit of delay for rough adjustment. The DLL circuit section with the unit of delay for rough adjustment is initially set into operation and, if the locked state is established, phase adjustment by the DLL circuit section with the unit of delay for rough adjustment is discontinued. The amount of delay of the DLL circuit section with the unit of delay for rough adjustment is fixed and, while the locked state is still going on, the DLL circuit section with the unit of delay for fine adjustment is set into operation.

With such DLL circuit, the phase of the timing clock may be adjusted with the unit of delay for fine adjustment, even if the phase is appreciably offset due to, for example, the power supply noise. The amount of transient jitter may thus be suppressed to a small value of the order of the unit of delay for fine adjustment.

### [Patent Document 1]

Japanese Patent Kokai Publication No. JP-P2000-122750A

### SUMMARY

The entire disclosure of Patent Document 1 is incorporated herein by reference thereto.

The following analysis is given in the present invention.

If, with the DLL circuit, disclosed in Patent Document 1, the clock signal suffers from jitter, it is possible to reduce the amount of such jitter in the clock signal CLKo by the DLL circuit section for fine adjustment. However, there is certain time delay until the phase offset is detected by the DLL circuit section for fine adjustment and the so detected phase offset is reflected in the delay time of the variable delay circuit. Hence, the DLL circuit has practically no jitter reducing effect at all if jitter to be reduced has a shorter period.

According to a first aspect of the present invention, there is provided a semiconductor device comprising: a DLL circuit that outputs an input clock signal via a variable delay circuit as an output clock signal, and that controls the amount of delay in the variable delay circuit based on the result of phase comparison between the input and output clock signals. The semiconductor device comprises a phase correction circuit. The phase correction circuit inputs the input clock signal and the output clock signal. If, after the DLL circuit has become locked, the input clock signal and the output clock signal are out of phase relative to each other, the phase correction circuit corrects the phase of the input clock signal based on the phase of the output clock signal to output a resulting signal to the variable delay circuit.

According to a second aspect of the present invention, there is provided an information processing system comprising: a first semiconductor device that transmits a system clock signal and a second semiconductor device that receives the system clock signal. The second semiconductor device includes a DLL circuit that outputs the system clock signal via a variable delay circuit as an output clock signal and that controls the amount of delay in the variable delay circuit based on the result of comparison of the phase of the system clock signal and that of the output clock signal. The second semiconductor device also includes a phase correction circuit that inputs the input clock signal and the output clock signal. When the input clock signal and the output clock signal are out of phase relative to each other after the DLL circuit has become locked, the phase correction circuit corrects the phase of the input clock signal based on the phase of the output clock signal to output a resulting signal to the variable delay circuit.

According to a third aspect of the present invention, there is provided a method for controlling a semiconductor device in the controlling method, the semiconductor device includes a DLL circuit. The DLL circuit outputs an input clock signal via a variable delay circuit as an output clock signal and controls the amount of delay in the variable delay circuit based on the result of phase comparison between the input and output clock signals. The method comprises a step of affording the input clock signal to the variable delay circuit when the DLL circuit is not on a locked state, and a step of correcting the phase of the input clock signal based on the phase of the output clock signal to output a resulting signal to the variable delay circuit in case the input clock signal and the output clock signal are out of phase relative to each other with said DLL circuit being in a locked state.

The meritorious effects of the present invention are summarized as follows.

According to the present invention, the temporal position of the edge of the clock signal, input to reduce the jitter, is offset and delivered in this state to the variable delay circuit, resulting in an improved effect in reducing the jitter with a short period.

### BRIEF DESCRIPTION OF THE DRAWINGS

FIG. 1 is a block diagram showing a configuration of a DLL circuit according to an Example of the present invention.

FIG. 2 is a circuit diagram showing a configuration of a phase correction circuit according to an Example of the present invention.

FIG. 3 is a circuit diagram showing another configuration of the phase correction circuit according to the Example of the present invention.

FIG. 4 is a timing chart showing the operation of the DLL circuit according to the Example of the present invention.

FIG. 5 is a block diagram showing a configuration of an information processing system according to an Example of the present invention.

FIG. 6 is a block diagram showing another configuration of an information processing system according to the Example of the present invention.

### PREFERRED MODES

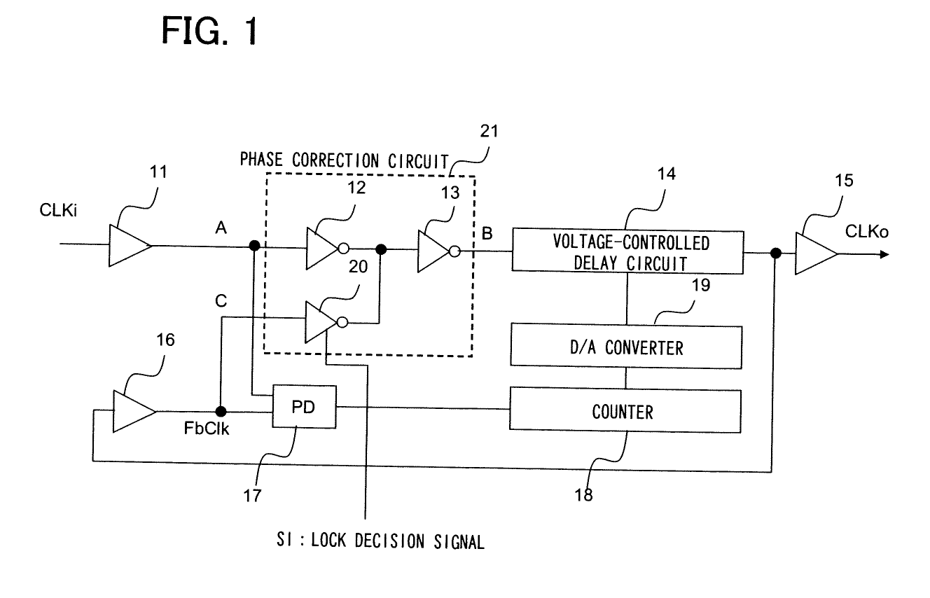

A DLL circuit according to an exemplary embodiment of the present invention outputs an input clock signal (CLKi of FIG. 1) via a variable delay circuit (14 of FIG. 1) as an output clock signal, and controls the amount of delay in the variable delay circuit based on the result of phase comparison between the input and output clock signals. The DLL circuit includes a phase correction circuit (21 of FIG. 1) that receives the input clock signal and the output clock signal. If, after the DLL circuit has become locked, the input clock signal and the output clock signal are out of phase relative to each other, the phase correction circuit corrects the phase of the input clock signal based on a phase of the output clock signal to output a so corrected signal to the variable delay circuit.

When the input clock signal and the output clock signal are out of phase relative to each other, the phase correction circuit in the DLL circuit may output the corrected signal whose phase is intermediate between a phase of the input clock signal and a phase of the output clock signal.

When the input clock signal and the output clock signal are out of phase relative to each other, the phase correction circuit of the DLL circuit may output the signal whose phase is closer to the output clock signal than a center point between a phase of the input clock signal and that of the output clock signal.

The phase correction circuit of the DLL circuit may include a first inverter supplied with the input clock signal and a second inverter supplied with the output clock signal. Outputs of the first and second inverter may be connected together.

The phase correction circuit of the DLL circuit may include a load element provided between a first power supply and a common node, and first and second MOS transistors connected in parallel between the common node and a second power supply. The first and second MOS transistors may be driven by the input clock signal and by the output clock signal, respectively.

The above mentioned DLL circuit may be configured as a semiconductor device. The semiconductor device may also constitute an information processing system.

If, with this DLL circuit, the input clock signal contains the jitter of a short period, such jitter is initially reduced at a preset ratio by the phase correction circuit, after which the clock signal is delivered to the variable delay circuit, thus reducing the jitter in the output clock signal.

Certain Examples of the present invention will now be described with reference to the drawings.

### Example 1

FIG. 1 depicts a block diagram showing the configuration of a DLL circuit according to an Example of the present invention. In FIG. 1, the DLL circuit includes an input buffer 11, a phase correction circuit 21, a voltage-controlled delay circuit 14, an output buffer 15, a replica output buffer 16, a phase detector (PD) 17, a counter 18, and a D/A converter 19. The DLL circuit further includes inverters 12, 13 and a clocked inverter 20.

The input buffer 11 inputs a clock signal CLKi from outside to output it to a phase correction circuit 21 and to one input terminal of the phase detector 17. The phase correction circuit 21 receives an output signal of the input buffer 11 (signal A) and an output signal of the replica output buffer 16 (signal C). When the DLL circuit is in the locked state, the clocked inverter 20 is activated with a lock decision signal S1 being in an H-state, for example. The phase correction circuit corrects the phase of the output signal of the input buffer 11 (signal A) at a preset ratio based on the phase of the output signal of the replica output buffer 16 (signal C) to output a phase-corrected signal (as an output signal B) to the voltage-controlled delay circuit 14. When the DLL circuit is in the non-locked state, the clocked inverter 20 is deactivated with the lock decision signal S1 being in the L-level state, for example. In this state, the output signal of the input buffer 11 (signal A) is output to the voltage-controlled delay circuit 14 without the signal undergoing the phase correction.

The voltage-controlled delay circuit 14 is a variable delay circuit exemplified by a voltage-controlled delay line (VCDL) controlling the amount of delay based on an output signal of the D/A converter 19. Specifically, the delay circuit 14 delays the output signal of the phase correction circuit 21 (signal B) to output the so delayed signal to the output buffer 15 and to the replica output buffer 16. The output buffer 15 buffers the output signal of the voltage-controlled delay circuit 14 to output the so buffered signal as a clock signal CLKo to outside.

The replica output buffer 16 buffers the output signal of the voltage-controlled delay circuit 14 to output the so buffered signal as a clock signal FbCLK to the phase correction circuit 21 and to the other input terminal of the phase detector 17.

The phase detector 17 compares the phase of the output signal of the input buffer 11 to that of the replica output buffer 16 (clock signal FbCLK). The result of comparison is output to the counter 18, which counts the result of comparison. The D/A converter 19 DA-converts the count result to deliver so converted count result to the voltage-controlled delay circuit 14 in order to control the amount of delay in the voltage-controlled delay circuit 14.

The phase correction circuit 21 is now described in more detail. The phase correction circuit 21 is configured to generate an output signal B from two input signals, namely the signals A and C. With the lock decision signal S1 at H-level, the phase correction circuit generates the signal B of a phase shifted from the phases of the signals A and C to an intermediate time point corresponding to a preset ratio internally dividing the time between the two phases by way of phase correction. If the lock decision signal S1 is at the L-level, no phase correction is made, with the signal A then being transmitted as it is as the signal B.

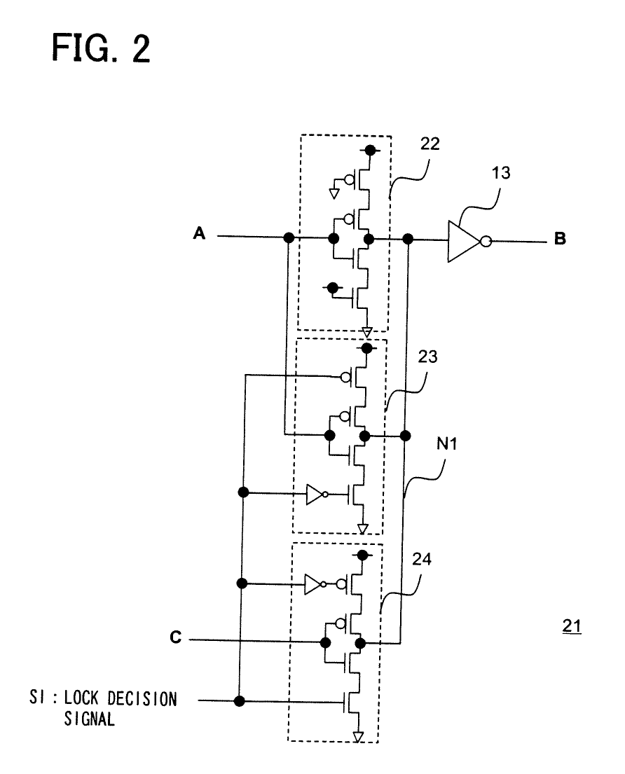

FIG. 2 depicts a circuit diagram showing an example of the phase correction circuit. Referring to FIG. 2, the phase correction circuit 21 includes an inverter 22, whose gate is supplied with the signal A, and a clocked inverter 23, whose gate is also supplied with the signal A. The phase correction circuit also includes a clocked inverter 24, whose gate is supplied with the signal C, and an inverter 13. An output node N1 is common to the inverter 22 and to the clocked inverters 23, 24, and is connected to an input of the inverter 13. An output of the inverter 13 is to be the output signal B of the phase correction circuit 21.

With the clock decision signal S1 at the L-level, the clocked inverter 23 is activated, while the clocked inverter 24 is deactivated. Hence, the node N1 is run in operation, in response only to the signal A, by the inverter 22 and the clocked inverter 23 connected in parallel to each other. If conversely the lock decision signal S1 is at the H-level, the clocked inverter 23 is deactivated, while the clocked inverter 24 is activated. Therefore, the node N1 is run in operation by the inverter 22 in response to the signal A, while also being run in operation by the clocked inverter 24 in response to the signal C. It is observed that, if the load driving capability, for example, of the clocked inverter 23 is set so as to be equal to that of the clocked inverter 24, there is no phase shift (correction) of the signal B, provided that the signals A and C are in phase with each other.

If jitter is contained in the clock signal CLKi, the signal A undergoes a phase offset, so that the signals A and C are out of phase relative to each other. As a result, the waveform at the node N1 becomes blurred. However, the waveform is shaped at the inverter 13 such that there may be obtained the signal B having a phase offset from the phases of the signals A and C to an intermediate time point corresponding to a preset ratio (obtained by internally dividing the time interval) between the two phases. As a result, the signal B with a corrected phase is generated. The amount of the phase correction is decided by the blurred state of the waveform at the node N1, such that, if the load driving capability of the inverter 22 bears a ratio of 1:1 with respect to that of the clocked inverter 24, the phase of the signal B is at a center point between the phases of the signals A and C. The amount of phase correction of the output signal may thus be set by affording the ratio of the load driving capability of the inverter 22 to that of the clocked inverter 24.

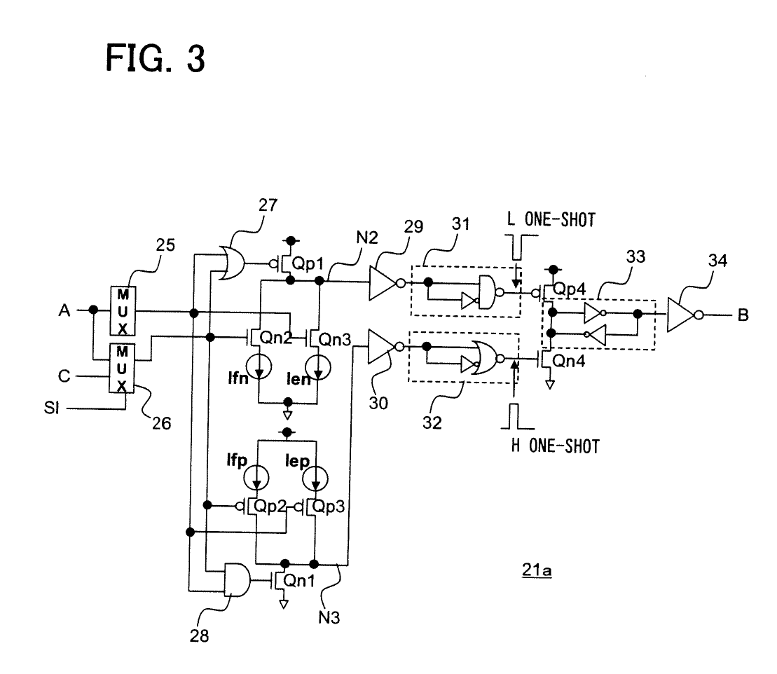

FIG. 3 depicts a circuit diagram showing another example of the phase correction circuit. Referring to FIG. 3, a phase correction circuit 21a includes a load MOS transistor Qp1, switching N-type MOS transistors Qn2, Qn3, load driving constant current sources Ifn, Ien, an OR gate 27, a waveform shaping inverter 29, a one-shot signal generator 31 and a flip-flop driving MOS transistor Qp4. These components perform the role of rise phase correction of the signals A and C. The phase correction circuit also includes a load MOS transistor Qn1, switching P-type MOS transistors Qp2, Qp3, load driving constant current sources Ifp, Iep, an AND gate 28, a waveform shaping inverter 30, a one-shot signal generator 32 and a flip-flop driving MOS transistor Qn4. These components perform the role of fall phase correction of the signals A and C. The phase correction circuit further includes multiplexers 25, 26, a flipflop 33 and an output buffer 34. The flipflop and the output buffer output the signal B.

The phase correction circuit 21a controls the rise phase correction and the fall phase correction of the signals A and C by respective independent circuits. Hence, the phase correction circuit has a feature that the rise phase correction and the fall phase correction can be controlled independently of each other. The rise phase correction of the signals A and C will now be described. The fall phase correction is the same as the rise phase correction except that the signal level of each circuit components is to be inverted from that for the rise phase correction. Hence, the description for the fall phase correction is dispensed with.

The multiplexer 25 is a dummy circuit for delay time matching, and is of the same circuit characteristic as that of the multiplexer 26. The multiplexer 25 is configured to select the signal A for all time. In case the signals A and C are out of phase relative to each other, the multiplexers 25, 26, respectively, drive the switching N-type MOS transistors Qn2, Qn3 with respective rise signal edges. Therefore, the fall speed at the node N2 is varied in keeping with the amount of phase offset to correct the rise phase of the output signal of the waveform shaping inverter 29. At this time, the amount of phase correction may freely be set by setting the current ratio of the load driving constant current sources Ifn, Ien. The amount of phase correction may also be adjusted by controlling the current values of the load driving constant current sources Ifn, Ien by a suitable control signal.

The one-shot signal generator 31 drives the flip-flop driving MOS transistor Qp4 by a one-shot pulse signal that goes LOW in keeping with the rise of the output signal of the waveform shaping inverter 29. The flip-flop driving MOS transistor Qp4 causes the output of the flipflop 33 to fall to L-level. The signal B, output from the output buffer 34, thus rises to H-level.

In similar manner, the one-shot signal generator 32 drives the flip-flop driving MOS transistor Qn4 by a one-shot pulse signal that goes HIGH in keeping with the fall of the output signal of the waveform shaping inverter 30. The flip-flop driving MOS transistor Qn4 causes the output of the flipflop 33 to rise to H-level. The signal B, output from the output buffer 34, thus falls to L-level.

With the above mentioned phase correction circuit, provided with the one-shot signal generators 31, 32, flip-flop driving MOS transistor Qp4, Qn4, flipflop 33 and the output buffer 34, it is possible to independently control rise phase correction and the fall phase correction of the signals A and C. These phase corrections may then be reflected in and integrated to the signal B.

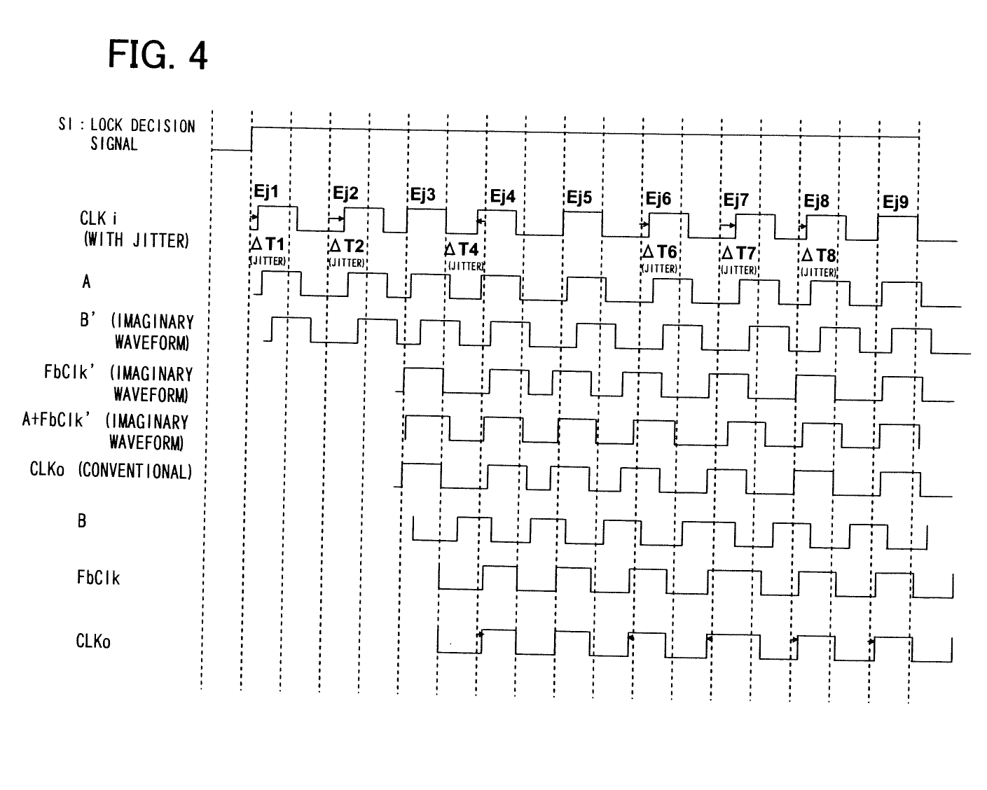

The operation of the DLL circuit will now be described. FIG. 4 depicts a timing chart for illustrating the operation of the DLL circuit according to an Example of the present invention. FIG. 4 shows operating waveforms with emphasis put on the jitter of the rise edges of the clock signal CLKi after the lock decision signal SI has become HIGH, that is, after the DLL circuit has become locked. It is observed that, as from start of the operation of the DLL circuit until the completion of phase lock, the operation of the clocked inverter 20 is discontinued by the lock decision signal SI to inhibit a malfunction from occurrence.

It is assumed that time offset (jitter) from an ideal edge of ΔTn, where n=1 to 9, has occurred in the clock signal CLKi. Since this time offset ΔTn may be varied from cycle to cycle, the waveform of the clock signal CLKi as shown is generated. That is, the clock signal has jitter of ΔTn at each rising edge. At the node A, which stands for an output of the input buffer 11, there appears a clock signal CLKi having a delay corresponding to the delay caused in the input buffer 11.

Supposing that the phase correction circuit 21 is not in operation, a signal B (imaginary waveform), output from the phase correction circuit 21, is delayed from the signal A in an amount corresponding to a delay caused in the phase correction circuit 21. At an output of the replica output buffer 16, there appears a clock signal FbCLk′ delayed from the signal B′ by the voltage-controlled delay circuit 14 and the replica output buffer 16.

When the phase correction circuit 21 is in operation, it outputs the signal B of a phase intermediate between the phase of the signal A and that of the clock signal FbCLk. The signal A is generated in response to the clock signal CLKi, and the clock signal FbClk is a past clock signal CLKi. The signal B is output as a signal delayed from the signal A by an amount of phase correction and an amount of delay caused in the phase correction circuit 21.

The signal B is delivered to the voltage-controlled delay circuit 14 and passed through the output buffer 15 to turn into the clock signal CLKo. It is also passed through the replica output buffer 16 to turn into the clock signal FbClk that is a feedback CLK.

As a result of the operation by the phase correction circuit 21, the signal B has a phase intermediate between a phase of the clock signal FbClk, which is a past clock signal CLKi, and that of the current clock signal CLKi. Thus, with the jitter ΔTn of the current clock signal CLKi and with the jitter ΔTn−n′ of the clock signal FbClk, an offset from the ideal edge of the signal at the node B is (ΔTn+ΔTn−n′)/2. That is, the jitter of the current clock signal CLKi and that of the past clock signal CLKi are averaged out to give an amount of jitter smaller than ΔTn. Hence, the jitter of the clock signal CLKo and that of the clock signal FbClk become small so that the peak jitter of the clock signal CLKo can be made smaller than the peak jitter of the clock signal CLKi.

The foregoing description has been made for a case in which, based on the phase of the clock signal CLKi and the clock signal FbClk, the phase of the signal B has been corrected so as to be at the center of the phases of these clock signals. However, this is not meant to limit the present invention. The signal B may thus be corrected so as to be variable in accordance with X: 1−X, where 0≦X≦1, with respect to the phase of the clock signal CLKi and that of the clock signal FbClk. Thus, with the phase correction circuit 21, having the function of adjusting the amount of correction, it is possible to optimize the jitter of the clock signal CLKo.

For example, if the phase correction circuit 21a is provided with independent phase correction functions for the rise and fall edges, as set out above with reference to FIG. 3, jitter may be reduced with respect to both the rise and fall edges, thus optimizing the phase correction.

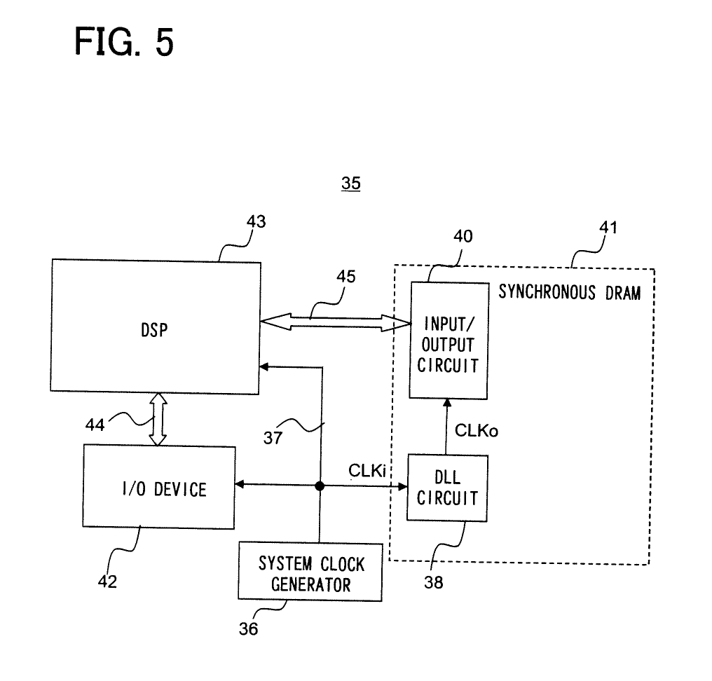

Several examples of application of the above mentioned DLL circuit to real systems will now be described. FIG. 5 shows an example formulation of an information processing system 35, such as a mobile phone or a computer system. The information processing system 35 includes a digital signal processor (DSP) 43, a synchronous DRAM 41, an input/output device (I/O device) 42, such as a keyboard or a display, and a system clock generator 36. The digital signal processor 43, synchronous DRAM 41 and the input/output device 42 are run in operation with a system clock as a reference clock. The system clock is generated by the system clock generator 36 and distributed via a system clock signal line 37. The information exchange between the digital signal processor 43 and the input/output device 42 is via a data bus 44, and that between the digital signal processor 43 and the synchronous DRAM 41 is via a data bus 45.

With the information processing system 35, set out above, a large volume of the information needs to be exchanged speedily and reliably. For this purpose, the information exchange is controlled in synchronism with the system clock. The system clock is distributed to many devices and may undergo phase offset or jitter due to noise between interconnections or to variations in the power supply potential. Hence, the system may be lowered in performance or may experience malfunctions. To remove or alleviate the phase offset or jitter, a clock synchronized delay control circuit may sometimes be incorporated in each of semiconductor devices that make up the system. The clock synchronized delay control circuit may be classified into a SAD system circuit and the DLL system circuit. Here, a case of the synchronous DRAM 41, as an example of incorporating the DLL circuit, is taken for explanation.

The synchronous DRAM 41 includes the aforementioned DLL circuit 38, generating the clock signal CLKo from the clock signal CLKi, as the system clock, and the input/output circuit 40. This input/output circuit 40 transmits/receives the address command information or data transmitted in synchronism with the clock signal CLKi via data bus 45 in response to the clock signal CLKo output from the DLL circuit 38.

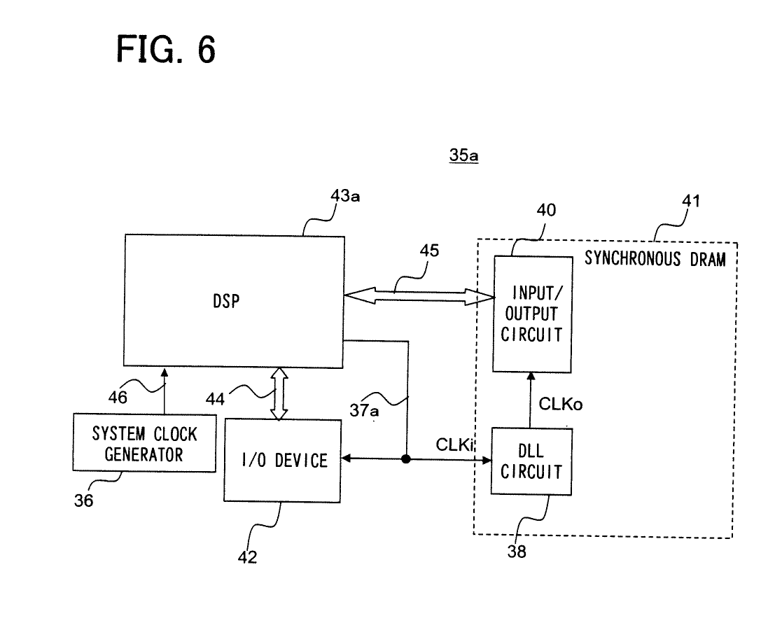

FIG. 6 shows another example formulation of an information processing system 35a. In FIG. 6, the same reference numerals as those of FIG. 5 depict the same parts or components. The system clock, generated by the system clock generator 36, is transmitted via signal line 46 to a digital signal processor 43a. This digital signal processor distributes the clock signal CLKi, which is to be a system clock, via a system clock line 37a to another device, such as the input/output device 42 or to the synchronous DRAM 41.

With this formulation, the phase offset or jitter in the system clock may be reduced to provide for high-speed information exchange between semiconductor devices in stability. It is thus possible to provide a high-performance semiconductor device and a high-performance information processing system.

The disclosure of the aforementioned Patent Document is incorporated by reference herein. The particular exemplary embodiments or examples may be modified or adjusted within the gamut of the entire disclosure of the present invention, inclusive of claims, based on the fundamental technical concept of the invention. Further, variegated combinations or selection of elements disclosed herein may be made within the framework of the claims. That is, the present invention may encompass various modifications or corrections that may occur to those skilled in the art in accordance with the gamut of the entire disclosure of the present invention, inclusive of claims and the technical concept of the present invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a DLL circuit that outputs an input clock signal via a variable delay circuit as an output clock signal, and that controls the amount of delay in said variable delay circuit based on the result of phase comparison between said input and output clock signals; said semiconductor device further comprising:
a phase correction circuit that receives said input clock signal and said output clock signal; said phase correction circuit, when said input clock signal and said output clock signal are out of phase relative to each other after said DLL circuit has become locked, correcting the phase of said input clock signal based on the phase of said output clock signal to output a signal to said variable delay circuit.

2. The semiconductor device according to claim 1 wherein, when said input clock signal and said output clock signal are out of phase relative to each other, said phase correction circuit outputs said signal whose phase is intermediate between a phase of said input clock signal and that of said output clock signal.

3. The semiconductor device according to claim 1 wherein, when said input clock signal and said output clock signal are out of phase relative to each other, said phase correction circuit outputs said signal whose phase is closer to said output clock signal than a center point between a phase of said input clock signal and that of said output clock signal.

4. The semiconductor device according to claim 1, wherein
said phase correction circuit comprises a first inverter supplied with said input clock signal and a second inverter supplied with said output clock signal; outputs of said first inverter and said second inverter being connected together.

5. The semiconductor device according to claim 1, wherein
said phase correction circuit comprises a load element provided between a first power supply and a common node, and first and second MOS transistors connected in parallel between said common node and a second power supply; said first MOS transistor being driven by said input clock signal; said second MOS transistor being driven by said output clock signal.

6. An information processing system comprising: a first semiconductor device that transmits a system clock signal and a second semiconductor device that receives said system clock signal;
said second semiconductor device comprising a DLL circuit that outputs said system clock signal via a variable delay circuit as an output clock signal and that controls the amount of delay in said variable delay circuit based on the result of comparison of a phase of said system clock signal and that of said output clock signal;
said second semiconductor device also comprising a phase correction circuit receiving said system clock signal and said output clock signal; said phase correction circuit, when said system clock signal and said output clock signal are out of phase relative to each other after said DLL circuit has become locked correcting a phase of said system clock signal based on a phase of said output clock signal to output a resulting signal to said variable delay circuit.

7. A method for controlling a semiconductor device comprising:
providing a DLL circuit that outputs an input clock signal via a variable delay circuit as an output clock signal, and that controls the amount of delay in said variable delay circuit based on the result of phase comparison between said input and output clock signals;
said method further comprising:
affording said input clock signal to said variable delay circuit when said DLL circuit is not in a locked state; and
correcting a phase of said input clock signal based on a phase of said output clock signal to output a resulting signal to said variable delay circuit in case said input clock signal and said output clock signal are out of phase relative to each other with said DLL circuit being in a locked state.
